(19) United States
(12) Patent Application Publication
(10) Pub. No.: US 2014/0227460 A1
(43) Pub. Date: Aug. 14, 2014

(54) METHODS FOR ADDRESSING INBOARD-OUTBOARD ASYMMETRY IN SUBSTRATE PROCESSING

(71) Applicant: Hariharakeshava Sarpangala Hegde, Fremont, CA (US)

(72) Inventor: Hariharakeshava Sarpangala Hegde, Fremont, CA (US)

(21) Appl. No.: 13/765,631

(22) Filed: Feb. 12, 2013

(51) Int. Cl. C23C 14/50; C23C 14/46

(52) U.S. Cl. CPC C23C 14/50; C23C 14/46
USPC 427/595

(57) ABSTRACT

Methods for performing ion beam deposition in a manner that substantially reduces or substantially eliminates the inboard-outboard asymmetry problem are disclosed. The method includes selecting an optimal deposition plume on test substrates and determining whether the optimal deposition plume is directed more toward the top or the bottom of a test substrate. If the optimal deposition plume is directed more toward the top of the test substrate, the production substrate is tilted negatively during production processing. If the optimal deposition plume is directed more toward the bottom of the test substrate, the production substrate is tilted positively during production processing.

### BACKGROUND OF THE INVENTION

Deposition techniques have been developed over time to process substrates (e.g., wafer) to produce electronic devices (such as integrated circuits, display panels, magnetic read/write heads, and the like). Long throw sputter deposition is an example deposition technique that has long been employed in the art.

Prior art U.S. Pat. No. 6,716,322 (issued Apr. 6, 2004) discussed the problem with inboard-outboard asymmetry during material deposition using long throw sputter deposition. Inboard-outboard asymmetry occurs when one side of a topographical feature (such as a trench or a protrusion) receives more deposition or has a different deposition profile compared another side of the same feature. Inboard-outboard asymmetry is to be distinguished from what is commonly referred to as “uniformity” since the inboard-outboard asymmetry problem affects the amount of deposition or the deposition profile on/at different sides of a given feature. In contrast, uniformity refers generically to how even the process rate (either etch or deposition) occurs at different points on the wafer and does not refer to the imbalance on/at different sides of a single topographical feature.

To elaborate, FIG. 1 shows a simplified example long throw directional sputter deposition arrangement, such as ion beam deposition. In the example of FIG. 1, a deposition flux source 102 generates and directs a beam of ions 104 toward a sputter target 106. The ions impinge upon sputter target 106 to produce a sputter plume 108, which contains the target material or compounds thereof. The sputter plume 108 is directed toward a substrate 110 to deposit material on substrate 110. The deposition is primarily line-of-sight, meaning that a surface of a topographical feature on substrate 110 needs to be line-of-sight with respect to sputter plume 108 in order to receive meaningful deposition. If a surface of a feature (whether a recessed feature such as a trench or a protruded feature such as a protrusion) is shadowed and/or is not line-of-sight with respect to sputter plume 108, meaningful material deposition does not occur. Although sputter plume 108 is represented by an arrow in the simplified drawing of FIG. 1, it should be understood that that the sputter plume may have a Gaussian distribution and typically diverges from a point source or small region on sputter target 106 and expands as it travels toward the substrate 110.

Substrate 110 is typically mounted on a substrate fixture that allows the substrate to be tilted as well as rotated during deposition. Generally speaking, deposition recipes for a given deposition process typically specify in advance the degree of tilt of substrate 110. Sputter target 106 is also tilted with respect to the central axis of ion beam 104 to ensure that sputter plume 108 is properly directed at substrate 110 as material is sputtered off sputter target 106 by ion beam 104.

For technical reasons, ion beam 104 needs to be focused at the center of sputter target 106. One of these reasons is to avoid stray ions from missing sputter target 106 and undesirably impinging on other surfaces of the processing chamber, which then undesirably sputtering material from other surfaces of the processing chamber. Such unwanted sputtering creates undesirable contamination of the deposited material on the substrate surface, which in turn degrades the performance of the devices being formed on the substrate. Accordingly, ion beam 104 may be thought of as focusing at the center of sputter target 106 during processing.

The practical effect of focusing ion beam 104 at the center of sputter target 106 is that the sputtered material does not travel parallelly from the surface of sputter target 106 to the surface of substrate 110. Rather, the sputtered plume 108 has a diverging profile, emanating from a center point or small central region of sputter target 106 and diverging while being directed toward substrate 110. With respect to the example of FIG. 1, the material in sputter plume 108 has a longer distance to travel to features at the upper edge of the substrate (e.g., feature 120) compared to features at the center of the substrate (e.g., feature 122) or features at the lower edge of the substrate (e.g., feature 124).

More importantly, the outboard side 134 of feature 120 (defined as the side or surface facing away from the substrate center) is shadowed by the feature itself and receives less or insignificant deposition while the inboard side 132 (defined as the side or surface facing toward the substrate center) has line-of-sight to sputter plume 108 and receives more or a significant amount of deposition relative to the outboard side 134. Feature 124 at the bottom of substrate 110 may also suffer inboard-outboard asymmetry to some degree. Generally speaking, features at the center of the substrate such as feature 122 tend to suffer the least inboard-outboard asymmetry relative to features at the periphery of the substrate (such as feature 120 or feature 124).

One way to address this inboard-outboard asymmetry in the prior art is to rotate the substrate (e.g., about 10-50 RPM) while depositing. However, it has been found that such substrate rotation does not completely eliminate the inboard-outboard asymmetry problem. Various approaches have been proposed in the prior art to further alleviate the inboard-outboard asymmetry problem, including the use of a shaped profiler mask in the aforementioned U.S. Pat. No. 6,716,322 as well as a scanning technique as disclosed in issued U.S. Pat. No. 7,879,201.

While the aforementioned prior art approaches have succeeded in reducing inboard-outboard asymmetry in some situations, these approaches involve some tradeoffs in the form of increased complexity, increased chamber maintenance and/or reduced deposition efficiency. Consequently, manufacturers continue to try to find alternative or improved ways to reduce inboard-outboard asymmetry for long throw directional sputter deposition processes.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 shows a simplified example long throw directional sputter deposition arrangement to facilitate discussion.

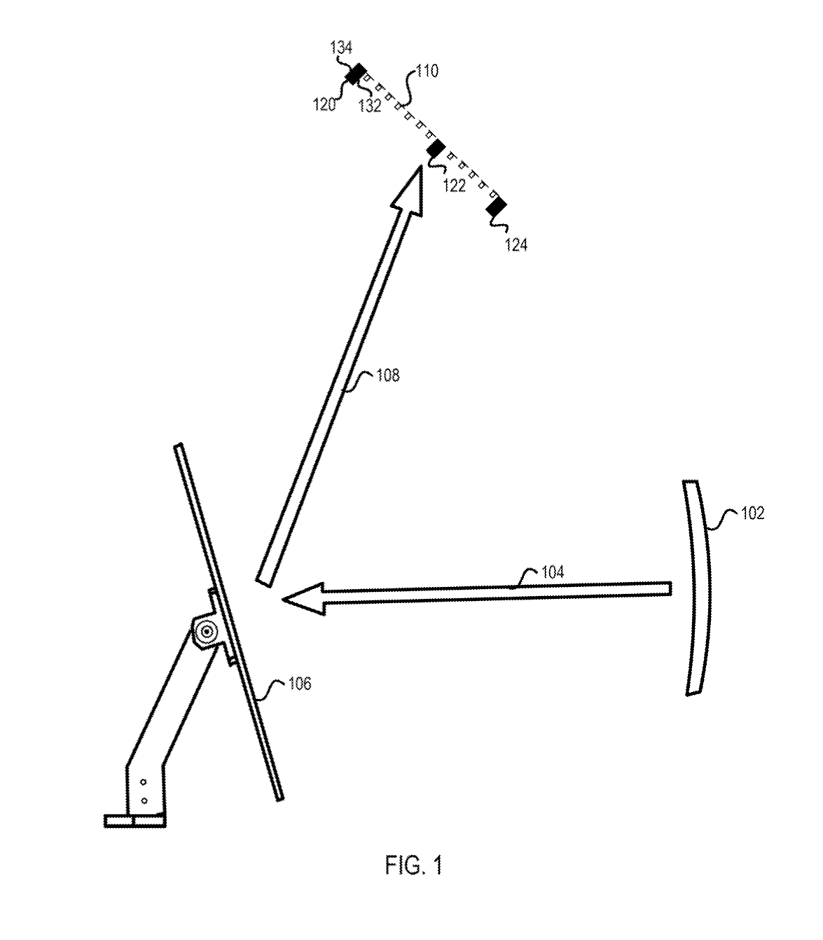

FIG. 2 shows another simplified example long throw directional sputter deposition arrangement to facilitate discussion of tilt directionality.

FIG. 3 shows yet another simplified example long throw directional sputter deposition arrangement, including tilted targets and resulting deposition plumes to facilitate discussion of substrate tilt directionality.

FIG. 4 shows yet another simplified example long throw directional sputter deposition arrangement, including tilted targets and other resulting deposition plumes to facilitate discussion of substrate tilt directionality.

FIG. 5 shows, in accordance with an embodiment of the invention, the steps for performing ion beam deposition with inboard-outboard asymmetry reduction.

### DETAILED DESCRIPTION OF EMBODIMENTS

The present invention will now be described in detail with reference to a few embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

Various embodiments are described herein below, including methods and techniques. It should be kept in mind that the invention might also cover articles of manufacture that includes a computer readable medium on which computer-readable instructions for carrying out embodiments of the inventive technique are stored. The computer readable medium may include, for example, semiconductor, magnetic, opto-magnetic, optical, or other forms of computer readable medium for storing computer readable code. Further, the invention may also cover apparatuses for practicing embodiments of the invention. Such apparatus may include circuits, dedicated and/or programmable, to carry out tasks pertaining to embodiments of the invention. Examples of such apparatus include a general-purpose computer and/or a dedicated computing device when appropriately programmed and may include a combination of a computer/computing device and dedicated/programmable circuits adapted for the various tasks pertaining to embodiments of the invention.

Embodiments of the invention relate to methods for performing ion beam deposition in a manner that substantially reduces or substantially eliminates the inboard-outboard asymmetry problem. In one or more embodiments, the method includes determining the optimal deposition plume using a plurality of test substrates. The definition of“optimal deposition plume” will be explained later herein as embodiments of the invention are explained in greater detail.

During the process for determining the optimal deposition plume, a plurality of test substrates undergo deposition using the recipe that would be employed during production, except that the test substrates are not rotated and each test substrate is deposited using different combinations of target angle, ion beam intensity, gas composition and/or target material. Preferably (but not a limitation), the test substrates are held at zero-degree substrate tilt while the test substrates are deposited.

As the term is employed herein, one combination of target angle, ion beam intensity, gas composition, and/or target material is deemed to be different from another combination of target angle, ion beam intensity, gas composition, and/or target material if the value of at least one of these four parameters (target angle, ion beam intensity, gas composition, and/or target material) is different. For example, if the target angle alone changes from one combination to the next combination, these two combinations are deemed different even if their ion beam intensity, gas composition and target material may be the same. As another example, if the target material and ion beam intensity change but the gas composition and target material are the same, the two combinations are still deemed to be different.

Further, the different combinations of target angle, ion beam intensity, gas composition and/or target material are chosen such that the values of these parameters remain within a predefined permissible variation window for a deposition recipe that would be employed during production. For example, some recipes may allow argon to be substituted for neon as an inert gas component. Such change in the combination is permissible as being within the permissible variation window. As another example, some recipes may specify that the target angle may range from 18 degrees to 33 degrees. These ranges form the aforementioned permissible variation window for the production deposition recipe.

Once the plurality of test substrates are deposited using different combinations of target angle, ion beam intensity, gas composition, and/or target material, the test substrates are examined (using, for example, known metrology tools and/or techniques) to determine whether the optimal deposition plume is directed more toward the top of the substrate or more toward the bottom of the substrate.

As the term is employed herein, the “optimal” sputter plume represents the sputter plume that is focused the most toward either the upper edge or the most toward the bottom edge of the substrate. For example, if the examination of five 200 mm post-deposition test substrates reveals that deposition plume A associated with combination A is focused 50 mm from the upper edge of the substrate, deposition plume B associated with combination B is focused 40 mm from the upper edge of the substrate, deposition plume C associated with combination C is focused 30 mm from the upper edge of the substrate, deposition plume D associated with combination D is focused 20 mm from the upper edge of the substrate, and deposition plume E associated with combination E is focused 10 mm from the upper edge of the substrate, deposition plume E would be deemed the most optimal deposition plume for purposes of the invention.

As another example, if the examination of four 200 mm post-deposition test substrates reveals that deposition plume F associated with combination F is focused 30 mm from the upper edge of the substrate, deposition plume G associated with combination G is focused 40 mm from the bottom edge of the substrate, deposition plume H associated with combination H is focused 30 mm from the bottom edge of the substrate, deposition plume I associated with combination I is focused 20 mm from the upper edge of the substrate, deposition plume I would be deemed the most optimal deposition plume for purposes of the invention (in which case the optimal deposition plume is deemed to be focused.

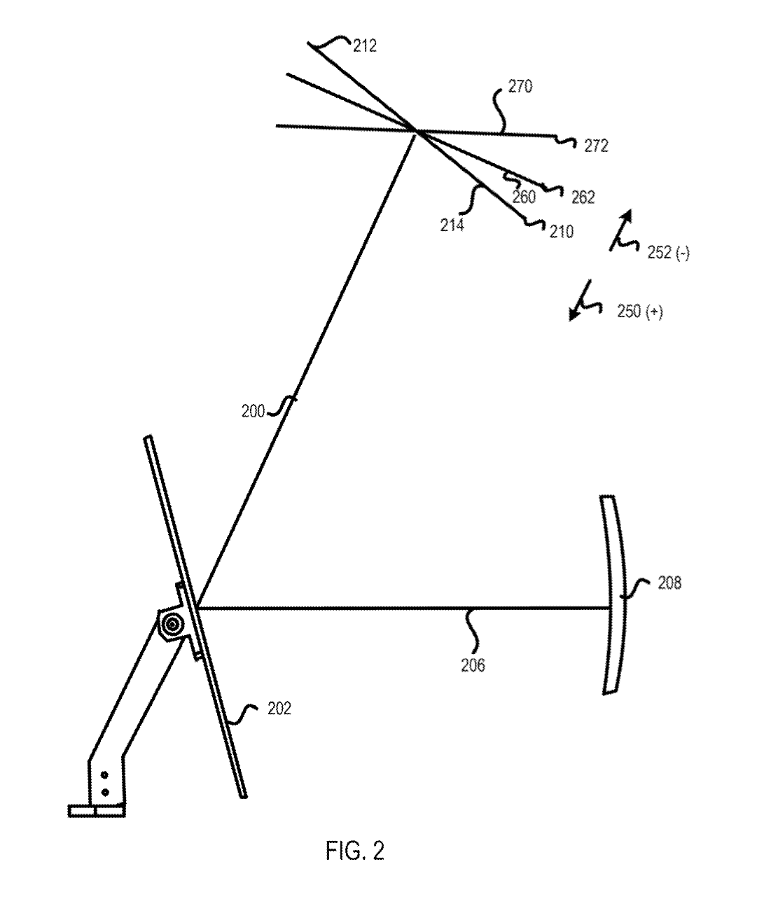

As the term is referred herein, bottom edge 210 of substrate 214 represents the edge of the substrate that is the closest to the imaginary source-target central axis (line 206 of FIG. 2). The top edge 212 of substrate 214 represents the substrate edge that is the furthest away from the imaginary source-target central axis (line 206 of FIG. 2). In FIG. 2, the imaginary source-target central axis is represented by imaginary line 206 that connects the center of the sputter target 202 to the center of the ion beam source 208.

As mentioned, the magnitude of the substrate tilt angle during deposition is predefined by the recipe. The substrate tilt angle is said to be zero when the substrate is perpendicular to the imaginary target-substrate central axis. With reference to FIG. 2, the imaginary target-substrate central axis is represented by imaginary line 200 that connects the center of sputter target 202 with the center of substrate 214. When substrate 214 is perpendicular to this imaginary target-substrate central axis, substrate 214 is deemed to be at zero-degree tilt. In FIG. 2, substrate 260 is at a zero-degree tilt since substrate 260 is perpendicular to the imaginary target-substrate central axis 200.

However, it is up to the process engineer to decide whether to tilt the substrate in a positive tilt angle or a negative tilt angle. As the term is employed herein, a substrate is said to be tilted in a positive tilt angle if its bottom edge is moved closer, relative to bottom edge in the zero-degree tilt position, to the imaginary target-substrate central axis 200. With reference to FIG. 2, bottom edge 210 of the substrate is tilted in a positive tilt angle if bottom edge 210 of the substrate is moved in the direction of arrow 250 to be closer, relative to bottom edge 262 of substrate 260 in the zero-degree tilt position, to the imaginary target-substrate central axis 200.

A substrate is said to be tilted in a negative tilt angle if its bottom edge is moved further away, relative to bottom edge in the zero-degree tilt position, from the imaginary target-substrate central axis. With reference to FIG. 2, bottom edge 272 of substrate 270 is tilted in a negative tilt angle if bottom edge 272 of substrate 270 is moved in the direction of arrow 252 to be further away, relative to bottom edge 262 of substrate 260 in the zero-degree tilt position, from the imaginary target-substrate central axis 200.

In accordance with one or more embodiments of the invention, if the sputter plume is directed more toward the top of the substrate than toward the bottom of the substrate (as an examination of the selected post-deposition test substrate would reveal), the substrate fixture (i.e., the fixture employed to hold the substrate during deposition) is tilted such that the substrate would be tilted negatively to alleviate the inboard-outboard asymmetry during production. On the other hand, if the sputter plume is directed more toward the bottom of the substrate than toward the top of the substrate (as an examination of the selected post-deposition test substrate would reveal), the substrate fixture (i.e., the fixture employed to hold the substrate during deposition) is tilted such that the substrate would be tilted positively to alleviate the inboard-outboard asymmetry during production. Keep in mind that the adjustment of the wafer tilt affects only whether the wafer tilt would be negative or positive since the magnitude of the tilt is typically determined in advance by the recipe.

In this manner, embodiments of the invention employ the tilt polarity (i.e., positive or negative) as a control knob to alleviate the inboard-outboard asymmetry. Such tilt polarity is innovatively determined based on whether the selected deposition plume is directed more toward the top of the selected test substrate than toward the bottom of the selected test substrate or more toward the bottom of the selected test substrate than toward the top of the selected test substrate. The determination of which deposition plume to select is based on a test process during which a plurality of test substrates are deposited, without substrate rotation, using different combinations of target angle, ion beam intensity, gas composition, and/or target material.

In this manner, no extra components (such as profile mask or scanning equipment as required by the prior art) need to be installed to achieve a reduction of the inboard-outboard asymmetry in accordance with embodiments of the invention. Further, with no impeding structures disposed between the substrate and the target during deposition (as would be required in the prior art), deposition may proceed at high efficiency during production,

The features and advantages of embodiments of the invention may be better understood with reference to the figures and discussion that follow.

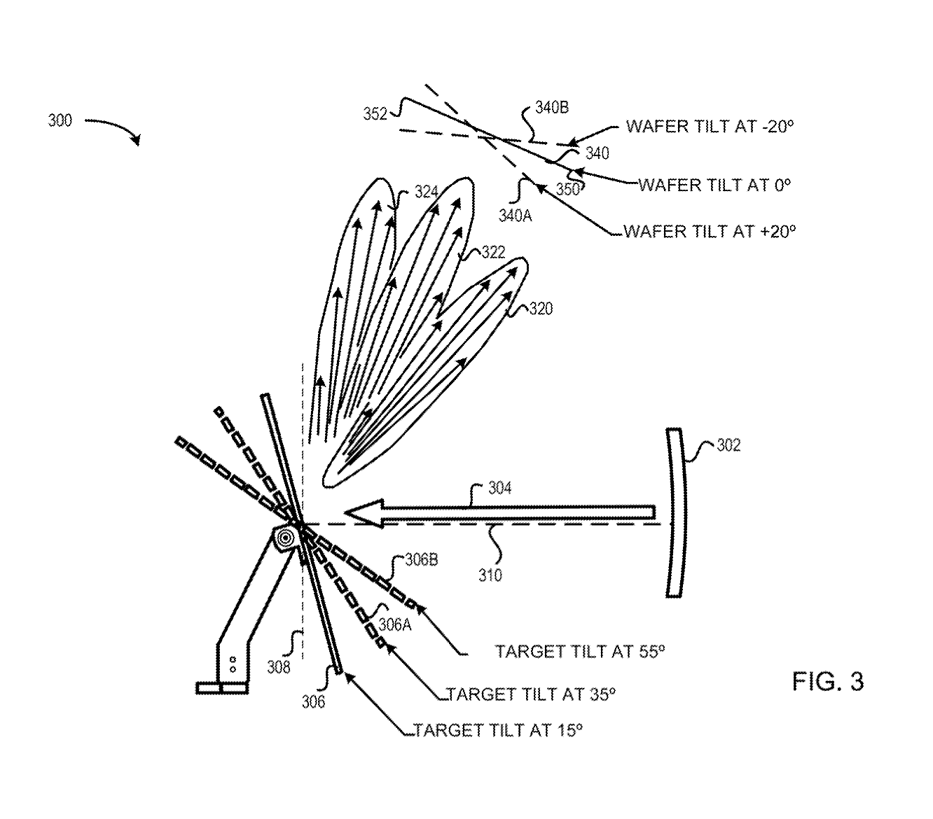

FIG. 3 show, in accordance with an embodiment of the invention, an example sputter deposition chamber including an ion beam sputter arrangement 300 in which a source 302 generates and directs a beam of ions 304 toward a sputter target 306. In this example, sputter target 306 is tilted at a target tilt angle of 15 degrees (relative to the vector 308 that is perpendicular to the source-target central axis 310). By tilting sputter target 306 at different target tilt angles, different sputter plumes result. For example, when sputter target 306 is tilted at 15 degrees, the result is sputter plume 320. When sputter target 306 is tilted at 35 degrees resulting in sputter target 306A (shown in broken outline to distinguish from sputter target 306), the result is sputter plume 322. When sputter target 306 is tilted at 55 degrees resulting in sputter target 306B (shown in broken outline to distinguish from sputter target 306), the result is sputter plume 324.

In the example of FIG. 3, the three deposition plumes 320, 322, and 324 are shown to be focused at different regions of the substrate 340 (which is at zero-degree substrate tilt) as the target angle of deposition target 306 is changed. For example, deposition plume 320 is focused more toward bottom edge 350 than toward top edge 352 of substrate 340. Deposition plume 322 is focused toward the center of substrate 340. Deposition plume 320 is focused more toward top edge 352 than toward bottom edge 350 of substrate 340.

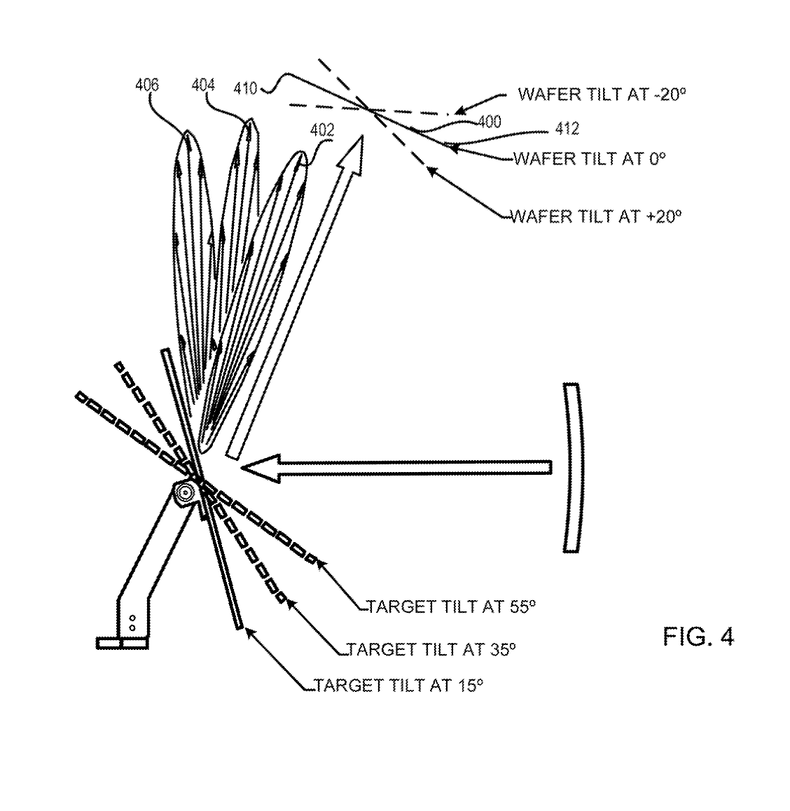

However, such is not always the case. In some recipes, increasing the tilt angle of the substrate target may not always cause the focus of the deposition plume to move from the bottom of the substrate to the top of the substrate. In some cases, the focus of the deposition plume may be more toward the bottom of the substrate than toward the top of the substrate irrespective of the target angle employed. In other cases, the focus of the deposition plume may be more toward the top of the substrate than toward the bottom of the substrate irrespective of the target angle employed. FIG. 4 shows this example whereby deposition plumes 402, 404, and 406 stay more focused toward the top 410 of the substrate 400 than toward the bottom 412 of the substrate 400 irrespective of the target angle employed. In still other cases, the changing of the target angle causes the plumes to behave in non-predictable ways.

Further, although the three deposition plumes 320, 322, and 324 of the example of FIG. 3 are shown to have the same sputter distribution (represented by the plume shape and the deposition intensity arrows therein), it is possible that the sputter distribution changes as the target angle is changed.

Because of this unpredictability in plume behavior as various combinations of deposition parameters are employed, embodiments of the invention ascertain the plume behavior by performing test deposition on a plurality of non-rotating test substrates using different combinations of target angle, ion beam intensity, gas composition, and/or target material and empirically determining the result by studying the post-deposition substrates, as discussed earlier. In one or more embodiments, only the target angle is varied during the test procedure.

The deposited test substrates are then examined (using, for example, known metrology tools and/or techniques) to determine which combination of target angle, ion beam intensity, gas composition, and target material produces the desired deposition effect such as a high deposition rate and/or high uniformity. At this point, inboard-outboard asymmetry may be ignored since the remedy of the inboard-outboard asymmetry problem is performed at the next step. The selected test substrate (i.e., the test substrate exhibiting the most desired quality) is then examined to determine whether the focus of the deposition plume that produces the selected test substrate is focused more toward the top of the substrate than toward the bottom of the substrate or vice versa.

If the sputter plume is directed more toward the top 352 of the substrate 340 than toward the bottom 350 of the substrate 340 (as in the case with plume 324 of FIG. 3), the substrate fixture (i.e., the fixture employed to hold the substrate during deposition) is tilted such that the substrate disposed thereon would be tilted negatively during production deposition to alleviate the inboard-outboard asymmetry. This is the case with substrate 340B of FIG. 3.

On the other hand, if the sputter plume is directed more toward the bottom 350 of the substrate 340 than toward the top 352 of substrate 340 (as in the case with plume 320 of FIG. 3), the substrate fixture is tilted such that the substrate disposed thereon would be tilted positively during production deposition to alleviate the inboard-outboard asymmetry. This is the case with substrate 340A of FIG. 3.

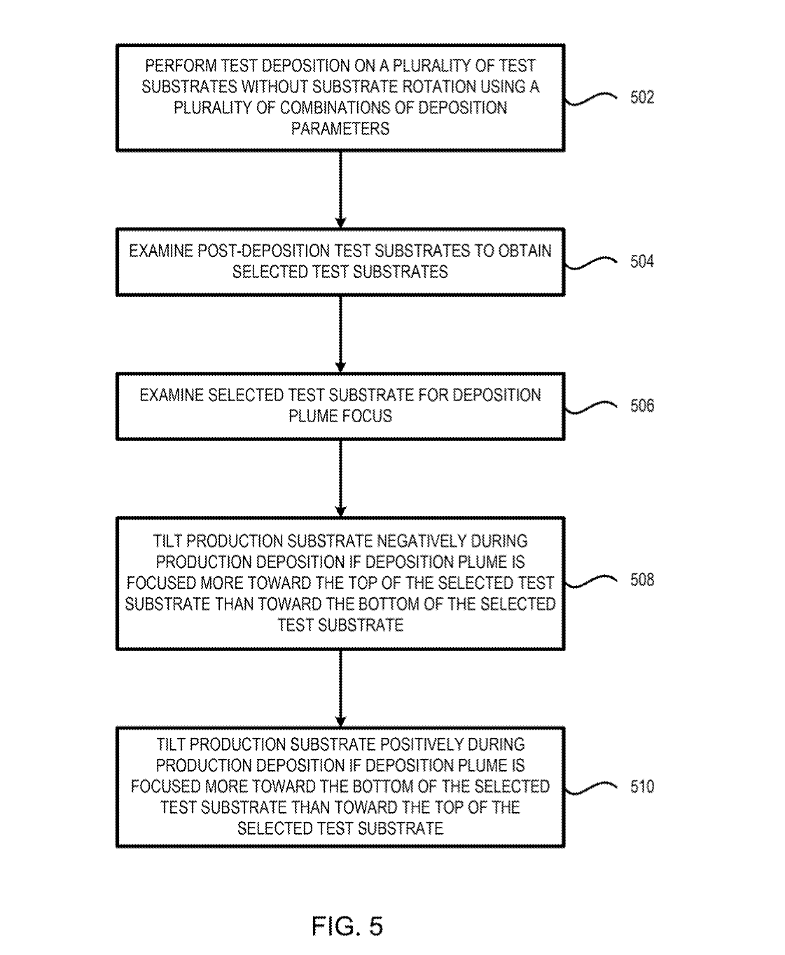

FIG. 5 shows, in accordance with an embodiment of the invention, the steps for performing ion beam deposition with inboard-outboard asymmetry reduction. In step 502, a plurality of test substrates are deposited using different combinations of target angle, ion beam intensity, gas composition and/or target material without rotating the test substrates during deposition. Preferably (but not an absolute requirement), the test substrates at held at a zero-degree tilt during test substrate deposition.

In step 504, the plurality of test substrates are examined after deposition to select at least one selected test substrate. The selected test substrate may represent a test substrate that satisfies some predefined criteria with respect to deposition rate and/or uniformity, for example.

In step 506, the test substrate selected is examined to determine whether the deposition plume employed to deposit on the selected test substrate is focused more toward the top of the substrate than toward the bottom of the substrate or more toward the bottom of the substrate than toward the top of the substrate.

In step 508, if the deposition plume employed to deposit on the selected test substrate is focused more toward the top of the substrate than toward the bottom of the substrate, a negative tilt polarity is selected for the substrate fixture during production and the same combination of target angle, ion beam intensity, gas composition and target material that produces the deposition result on the selected test substrate is employed for production purposes on production substrates while the production substrate is held at the negative tilt polarity.

In step 510, if the deposition plume employed to deposit on the selected test substrate is focused more toward the bottom of the substrate than toward the top of the substrate, a positive tilt polarity is selected for the substrate fixture during production and the same combination of target angle, ion beam intensity, gas composition and target material that produces the selected test substrate is employed for production purposes on production substrates while the production substrate is held at the positive tilt polarity.

It should be noted that in contrast to test substrate deposition, the production substrates are rotated during production deposition.

When substrate tilt polarity and the combination of target angle, ion beam intensity, gas composition and/or target material are selected in this manner, the inboard-outboard asymmetry problem is significantly reduced during production. More importantly, the reduction of the inboard-outboard asymmetry does not come at the expense of deposition efficiency or increased maintenance (as in the case with prior art techniques that employ some form of mask interposed between the target and the substrate). Furthermore, since no additional components are required to perform the inboard-outboard asymmetry reduction technique of embodiments of the invention, no expensive and/or complicated chamber retrofitting and/or chamber replacement is required. This is again unlike prior art approaches that require the chamber to be retrofitted with a mask and/or with structures to support scanning.

While this invention has been described in terms of several preferred embodiments, there are alterations, permutations, and equivalents, which fall within the scope of this invention. If the term “set” is employed herein, such term is intended to have its commonly understood mathematical meaning to cover zero, one, or more than one member. The invention should be understood to also encompass these alterations, permutations, and equivalents. It should also be noted that there are many alternative ways of implementing the methods and apparatuses of the present invention. Although various examples are provided herein, it is intended that these examples be illustrative and not limiting with respect to the invention.

What is claimed is:

1. A method for performing ion beam sputter deposition in a deposition chamber, said chamber having at least a substrate fixture and a sputter target, comprising:
ascertaining a selected deposition plume by
depositing material on a plurality of test substrates without substrate rotation using a plurality of different combinations of target angle, ion beam intensity, gas composition, and target material, and
selecting a test substrate among said plurality of test substrates after said depositing, said selected deposition plume corresponding to a deposition plume employed to deposit on said test substrate;
determining whether said selected deposition plume is focused toward an top edge or a bottom edge of said test substrate;
if said selected deposition plume is focused toward said top edge, tilting said substrate fixture at a negative tilt angle relative to an axis between a center of said sputter target; and
if said selected deposition plume is focused toward said bottom edge, tilting said substrate fixture at a positive tilt angle relative to an axis between a center of said sputter target.

2. The method of claim 1 further comprising employing, after said tiling at said negative angle or said tilting at said positive angle, a combination of said target angle, said ion beam intensity, said gas composition, and said target material that corresponds to said selected deposition plume to perform said ion beam sputter deposition on a production substrate in said deposition chamber.

3. The method of claim 2 wherein said plurality of different combinations of target angle, ion beam intensity, gas composition, and target material represent combinations that are within a predefined permissible variation window for a recipe employed for said ion beam sputter deposition on said production substrate.

4. A method for performing ion beam sputter deposition in a deposition chamber, said performing employs a recipe that specifies at least a substrate tilt angle, said chamber having at least a substrate fixture and a sputter target, comprising:
ascertaining a selected deposition plume by
depositing material on a plurality of test substrates without substrate rotation using a plurality of different combinations of target angle, ion beam intensity, gas composition, and target material, and
selecting a test substrate among said plurality of test substrates after said depositing, said selected deposition plume corresponding to a deposition plume employed to deposit on said test substrate;
determining whether said selected deposition plume is focused toward an top edge or a bottom edge of a substrate if said substrate is positioned on said substrate fixture;
if said selected deposition plume is focused toward said top edge, tilting said substrate fixture at a negative tilt angle relative to an axis between a center of said sputter target while keeping a magnitude of tilt of said substrate fixture at said substrate tilt angle; and
if said selected deposition plume is focused toward said bottom edge, tilting said substrate fixture at a positive tilt angle relative to an axis between a center of said sputter target while keeping said magnitude of tilt of said substrate fixture at said substrate tilt angle.

5. The method of claim 4 further comprising employing, after said tiling at said negative angle or said tilting at said positive angle, a combination of said target angle, said ion beam intensity, said gas composition, and said target material that corresponds to said selected deposition plume to perform said ion beam sputter deposition on a production substrate in said deposition chamber.

6. The method of claim 5 wherein said plurality of different combinations of target angle, ion beam intensity, gas composition, and target material represent combinations that are within a predefined permissible variation window for a recipe employed for said ion beam sputter deposition on said production substrate.

7. A method for performing ion beam sputter deposition in a deposition chamber, said performing employs a recipe that specifies at least a substrate tilt angle, said chamber having at least a substrate fixture and a sputter target, comprising:
ascertaining a selected deposition plume by
depositing material on a plurality of test substrates without substrate rotation using a plurality of different target angles, and
selecting a test substrate among said plurality of test substrates after said depositing, said selected deposition plume corresponding to a deposition plume employed to deposit on said test substrate;
determining whether said selected deposition plume is focused more toward an top edge or more toward a bottom edge of a substrate if said substrate is positioned on said substrate fixture;
if said selected deposition plume is focused more toward said top edge than toward said bottom edge, tilting said substrate fixture at a negative tilt angle relative to an axis between a center of said sputter target while keeping a magnitude of tilt of said substrate fixture at said substrate tilt angle; and
if said selected deposition plume is focused more toward said bottom edge than toward said top edge, tilting said substrate fixture at a positive tilt angle relative to an axis between a center of said sputter target while keeping said magnitude of tilt of said substrate fixture at said substrate tilt angle.

8. The method of claim 7 further comprising employing, after said tiling at said negative angle or said tilting at said positive angle, a target angle that corresponds to said selected deposition plume to perform said ion beam sputter deposition on a production substrate in said deposition chamber.

9. The method of claim 8 wherein said plurality of different target angles represent target angles that are within a predefined permissible variation window for a recipe employed for said ion beam sputter deposition on said production substrate.
